(19) United States
(12) Patent Application Publication
(10) Pub. No.: US 2025/0119662 A1
(43) Pub. Date: Apr. 10, 2025

(54) IMAGE SENSOR

(71) Applicant: Arnold & Richter Cine Technik GmbH & Co. Betriebs KG, München (DE)

(72) Inventor: Michael CIESLINSKI, München (DE)

(21) Appl. No.: 18/378,321

(22) Filed: Oct. 10, 2023

(30) Foreign Application Priority Data
Oct. 6, 2022 (DE) 102022125838.6

(51) Int. Cl. H04N 25/704; H04N 25/11; H04N 25/78

(52) U.S. Cl. CPC H04N 25/704; H04N 25/11; H04N 25/78

(57) ABSTRACT

An image sensor, in particular a CMOS image sensor, for an electronic camera has a plurality of pixels which are arranged in rows and columns and each of which is associated with one of at least three color channels. Each pixel comprises at least one light-sensitive detector element and a color filter. Each pixel that is associated with a first color channel of the three color channels comprises at least two light-sensitive detector elements that are configured to generate electrical signals independently of one another in dependence on incident light so that a phase difference between the electrical signals generated by the detector elements of the respective pixel can be used for an autofocus of the camera. Of the pixels that are not associated with the first color channel, at least some, in particular all, comprise only a single light-sensitive detector element that is configured to generate electrical signals in dependence on incident light.

The invention relates to an image sensor, in particular a CMOS image sensor, for an electronic camera, said image sensor comprising a plurality of pixels which are arranged in rows and columns and each of which is associated with one of at least three color channels, wherein each pixel comprises at least one light-sensitive detector element, which is configured to generate electrical signals in dependence on incident light, and a color filter that filters the light prior to incidence on the at least one detector element in accordance with the color channel with which the respective pixel is associated.

Electronic cameras may usually be used both as a still image camera and as a motion picture camera. As a motion picture camera, an electric camera may in particular be used to record image sequences. If recorded image sequences of this kind are to be reproduced with a high resolution on a large surface, for example on the screen of a cinema, it is important that the respective camera has a high image quality. This is because in particular cinema productions usually have very high standards and image defects are easily recognizable when projected onto a large screen.

Electronic cameras include an image sensor that converts light entering the camera through a lens of the camera and ultimately incident on the image sensor into electrical signals. The image sensor comprises a plurality of pixels that each comprise a light-sensitive detector element that generates electric charge according to the intensity of the light incident on the respective pixel. Since each pixel comprises a color filter, only that portion of the light which the respective color filter transmits, and which thus has a color corresponding to the color filter, is incident on the at least one detector element of the respective pixel. As a result, each pixel is associated with a color channel corresponding to the color (spectral range) of its respective color filter. For the reading out of the image (i.e. a single frame of the image sequence), the pixels are addressed in order via readout electronics and a voltage proportional to the respective charge of the pixels is conducted to a signal output of the image sensor.

It is important for the quality of an image recording that the recorded subject is sharply imaged. For this purpose, the focus of the camera has to be set correctly, i.e. the focal plane of the lens of the camera has to set such that the subject lies in the focal plane. For example, in the case of a portrait image, the focal plane should as a rule be set to the eye facing the camera.

If the lens of the camera is adjustable by a motor, there is the possibility of an automated focusing (so-called autofocus). For this purpose, the camera has to generate a control signal for the focus drive in order to move the focal plane to the correct position. Different autofocus methods are known for determining the control signal.

Some of these methods use external sensors that can, for example, be based on ultrasound measurement or stereoscopy to determine the optimal focus setting. Since, in these methods, the respective subject is captured from the angle of view of the respective external sensor, and thus from a different angle of view than that of the camera, a parallax always results that may lead to errors in focusing. The use of such methods for recordings with high quality requirements is thereby limited.

Such parallax errors may be avoided by methods in which the respective subject is captured by the lens of the camera for the determination of the focus setting. Therefore, such “internal” autofocus methods are generally less limited and more accurate than methods that use external sensors.

Methods in which the focus setting is determined by the lens of the camera may be divided into two classes: on the one hand, methods that use an additional sensor that is independent of the image sensor of the camera used for the actual recording and, on the other hand, methods that use the image sensor itself to determine the correct focus setting.

For methods with an additional sensor, it is necessary to reflect a portion of the light that enters the camera through the lens in the direction of the additional sensor. The mirror needed for this purpose requires additional installation space that enlarges the camera and that is not available with modern lenses. Furthermore, due to the reflection, a portion of the light is lost for the image recording.

Therefore, methods are advantageous in which the image sensor used for the recording is also used to determine the correct focus setting. Two basic principles are known for such methods: the contrast autofocus, on the one hand, and the autofocus by means of PDAF pixels, on the other hand, where PDAF stands for “Phase Detection Auto Focus”.

With a contrast autofocus, the focal plane is first traversed and the position with the maximum sharpness is determined, wherein the sharpness is determined based on the contrast of the image recorded in the respective position. At this position, the focal plane is allowed to oscillate with a low amplitude in order to find the optimal position and then to track it, i.e. to continuously readjust it. While this method works very well for still image recordings, the focal plane perceptibly oscillating in the moving image is disturbing in motion picture recordings, however. The reason for the oscillation is that, with such a method, no direct information about the degree of defocusing is obtained, nor is it known in which direction the focal plane must be adjusted for a correct focusing. This information only results from the traversing of the focal plane. Due to the disturbing oscillation, a contrast autofocus is usually not considered for high-quality motion picture recordings, such as cinema productions.

With an autofocus with PDAF pixels, these disadvantages do not exist since the relative position of the lens to the current focal plane may be determined directly from the data of the image sensor by means of which the images are recorded. However, the image sensor has to have special pixels for this purpose, the so-called PDAF pixels. Such a PDAF pixel can, for example, be formed by arranging a plurality of ordinary pixels (for example, two) under a common microlens or by covering half of a pixel by a masking. Because both options make it possible to determine whether there is a phase difference in the respective signals generated between different regions (halves) of the PDAF pixels, which is an indication that the corresponding subject is not in focus. At the same time, by means of the magnitude and the sign of the phase difference, it may be determined by how much and in which direction the focus has to be adjusted so that the subject is imaged sharply.

There are various strategies for arranging the PDAF pixels on the image sensor. For example, a plurality of individual rows of the image sensor may be completely or at least largely occupied by PDAF pixels. Alternatively thereto, the PDAF pixels may be arranged in a scattered manner, i.e. individual PDAF pixels or pairs of PDAF pixels are distributed at a spacing from one another over the image sensor. Alternatively thereto, it is further known to form all the pixels of an image sensor as PDAF pixels, namely either as pixel pairs whose two pixels are arranged under a common microlens, or as groups of four pixels in a 2×2 arrangement under a common microlens.

Since the PDAF pixels have a different design than the other pixels of the image sensor, they may, if they are—as explained—arranged row-wise or in a scattered manner, only contribute to a very limited extent (if at all) to the image information obtained by means of the other pixels for the image to be recorded. As a rule, the image information at a pixel that corresponds to a PDAF pixel therefore has to be interpolated as if the PDAF pixel were a defective pixel. If the image quality requirements are very high, often not even the image information of the direct neighbors of a PDAF pixel may be used for the interpolation since they also differ in their properties from normal pixels. Therefore, in applications that require high quality, a row-wise or scattered arrangement of PDAF pixels is not usable.

In a full-area arrangement, i.e. when all the pixels of the image sensor are configured as PDAF pixels, these disadvantages are indeed avoided. However, the data rate, i.e. the amount of image information that has to be processed per unit of time to achieve a certain resolution at a certain frame rate, is thereby at least doubled (possibly even quadrupled). A doubled data rate is also accompanied by a doubling of the power dissipation. This is because not only must twice the amount of data be output by the sensor to downstream processing electronics, but this double amount of data must also be processed there. The power required for this purpose also leads to an increase in the heat generated, which is generally problematic for a camera. Nowadays, in some cases, even the construction size of a camera is determined to a considerable extent by the size of its cooling system. It is therefore endeavored to keep the data rate as low as possible.

It is an object of the invention to provide an image sensor that enables a particularly reliable automatic focus setting, that only requires a comparatively low data rate, and that also otherwise avoids the disadvantages mentioned as far as possible so that it is in particular also suitable for recording motion picture data as part of productions with particularly high quality requirements.

The object is satisfied by an image sensor having the features of claim 1. Advantageous embodiments result from the dependent claims, the present description, and the FIGURE.

The image sensor in accordance with the invention, which is in particular a CMOS image sensor, is configured as an image sensor for an electronic camera, in particular for a motion picture camera, and has a plurality of pixels which are arranged in rows and columns and each of which is associated with one of at least three color channels.

The arrangement of the pixels in rows and columns is preferably a rigid two-dimensional arrangement in which the pixels are arranged regularly spaced apart from one another. In this regard, the arrangement may be considered as a pixel matrix. The course of the rows and the course of the columns are each preferably rectilinear. The columns are preferably oriented orthogonally to the rows. However, the columns may generally also be oriented obliquely to the rows. The arrangement of the pixels may in particular have an at least substantially rectangular shape. At least within an image region of the image sensor that is provided for the recording of a respective image, that may likewise in particular have an initially substantially rectangular shape and that may generally correspond to the entire arrangement of the pixels, each matrix point, i.e. each point of intersection of a row with a column of the arrangement, preferably forms a pixel. Furthermore, preferably no pixel extends over more than one row and no pixel extends over more than one column. (The same thus also applies to the components of a respective pixel, such as one or more detector elements, a color filter, or a microlens of the respective pixel, which will be discussed below.)

Exactly three color channels are preferably provided. The three color channels may in particular be a green color channel, a red color channel, and a blue color channel. More color channels, in particular four color channels, may generally also be provided. For example, a white color channel may be provided in addition to a green, a red, and a blue color channel. Where a pixel of a certain color channel is mentioned, this refers to a pixel that is associated with this color channel.

Each pixel comprises at least one light-sensitive detector element that is configured to generate electrical signals in dependence on incident light. A respective electrical signal may in particular be present in the form of electric charge that is generated by the detector element in dependence on light incident on the detector element, in particular on a detection surface of the detector element. The electric charge generated may in particular depend on the intensity or amount of the incident light within a certain exposure period. At the end of the exposure period, the electrical signal or the electric charge may be read out from the detector element, in particular by readout electronics of the image sensor provided for this purpose. The detector element may in particular be configured as a so-called pinned diode.

Furthermore, each pixel comprises a color filter that filters the light prior to incidence on the at least one detector element in accordance with the color channel with which the respective pixel is associated. This means that the color filter only transmits a portion of the light to the detector element, namely essentially only that portion of the light that is within a specific spectral range of (visible) light that corresponds to the color of the respective color channel. If the respective pixel comprises a plurality of detector elements, the color filter of the pixel extends over this plurality of detector elements so that only light of the color that corresponds to the color channel with which the respective pixel is associated is incident on all the detector elements of a respective pixel.

Each pixel may furthermore comprise a microlens that may be arranged along the optical path in front of or behind the color filter and that may serve to collect light incident on the respective pixel. If the respective pixel comprises a plurality of detector elements, the microlens of the pixel extends over this plurality of detector elements.

In accordance with the invention, each pixel that is associated with a first color channel of the three color channels comprises at least two light-sensitive detector elements that are configured to generate electrical signals independently of one another in dependence on incident light (on the respective detector element) so that a phase difference between the electrical signals generated by the detector elements of the respective pixel may be used for an autofocus function of the camera, whereas, of the pixels that are not associated with the first color channel, at least some of these pixels, preferably most, in particular all of these pixels, comprise only a single light-sensitive detector element that is configured to generate electrical signals in dependence on incident light (on the detector element).

If four color channels are provided, the pixels that are associated with the fourth color channel may also each comprise two detector elements. This may in particular be expedient if the fourth color channel is a white color channel. However, it may also be advantageous in the case of more than three color channels if only the pixels that are associated with the first color channel comprise two detector elements.

The designation of a respective color channel as the “first”, “second”, “third” or “fourth” color channel serves solely for the linguistic differentiation of the color channels. In particular, this designation is not intended to imply any hierarchy or order between the color channels. Every desired color may generally be considered as the color of the first color channel. If three color channels are provided, it is particularly expedient if the first color channel is a green color channel, i.e. if each pixel that is associated with the first color channel comprises a color filter that only transmits light of a green spectral range.

In general, if a color channel is designated as a color channel of a specific color (for example, “green color channel”), what is meant is that each pixel that is associated with this color channel comprises a color filter of the corresponding color, i.e. a color filter that only transmits light of a spectral range corresponding to the color so that the one or more detector elements of the respective pixel generates/generate electrical signals or electric charge in dependence on incident light of this color.

Each pixel that is associated with the first color channel preferably comprises exactly two detector elements. In general, however, there may also be more detector elements, for example a respective four detector elements. It is preferred if the detector elements of a respective pixel are arranged separately from one another, i.e. do not overlap. The plurality of detector elements of a respective pixel may be arranged adjacent to one another, in particular in a plane of the image sensor, and may adjoin one another along a preferably straight division line, preferably at a constant spacing from one another.

Since the pixels that are associated with the first color channel comprise at least two detector elements, they may be used as PDAF pixels, i.e. as pixels for determining a focus distance of the camera. For this purpose, a phase difference between the electrical signals or electric charges which are generated by the two or more detector elements of the respective pixel may, for example, be determined by means of an associated evaluation circuit. Based on the phase difference determined, a control signal for the focus drive for automatic focusing may then be determined.

Unlike the pixels that are associated with the first color channel, at least a (predominant) portion of the pixels that are not associated with the first color channel comprises only one detector element. These pixels are therefore not suitable as PDAF pixels and thus do not contribute to the autofocus, but preferably serve solely for the image generation. The pixels that are not associated with the first color channel are associated with one of the remaining color channels, i.e., in the case of a total of three color channels, with either a second color channel or a third color channel. If more than three color channels are provided, the pixels that are associated with a fourth color channel may either be configured in a manner corresponding to the pixels that are associated with the first color channel, i.e. that comprise at least two detector elements, or corresponding to the pixels that are associated with the second color channel or the third color channel, i.e. that in particular comprise only one detector element.

Consequently, in the case of the image sensor in accordance with the invention, whether a respective pixel of the image sensor has at least two detector elements and may thus be used as a PDAF pixel or not, does not primarily depend on the position of the respective pixel on the image sensor, but rather on which color channel the respective pixel is associated with. Since no less than 25% and no more than 50% of all the pixels of the image sensor are usually associated with a respective color channel, the image sensor in accordance with the invention, unlike known image sensors with PDAF pixels, does not have only a few PDAF pixels that are e.g. arranged row-wise or in a scattered manner, nor is it equipped with PDAF pixels over the full area. Similarly to a full-area arrangement of PDAF pixels, the PDAF pixels of the image sensor in accordance with the invention do not have to be interpolated, but may by all means contribute to the image information due to their design with at least two detector elements. Unlike a full-area arrangement, the data rate is, however, not doubled or quadrupled, but rather increases comparatively slightly.

For example, in an image sensor in which the color filters of the pixels are arranged in accordance with a Bayer mask, the data rate only increases to 150% if the first color channel is the green color channel with which 50% of the pixels are associated in a Bayer mask. Significant disadvantages in the operation of the image sensor may be avoided by such a moderate increase. Since the green color channel furthermore typically has a significantly higher light sensitivity compared to the other two color channels (red and blue), which may, for example, contribute to 180% of the light sensitivity of the red color channel, the different color channels are then even better matched to one another than in a conventional image sensor with a Bayer mask due to the fact that the pixels associated with the green color channel comprise two detector elements on each of which only approximately half of the amount of light is incident that is incident on the entire pixel.

In some embodiments, the pixels of the image sensor are arranged at positions that form a regular grid of rows and columns, wherein the at least two light-sensitive detector elements of the pixels of the first color channel are jointly arranged at a single position of the grid. Accordingly, each microlens of the image sensor may also be arranged at exactly one respective position of the grid.

In accordance with an advantageous embodiment, at least half of the pixels of the image sensor are associated with the first color channel. Due to such a high number of pixels, which may be used as PDAF pixels for an autofocus, the autofocus may take place particularly reliably.

In particular, exactly half of the pixels of the image sensor may be associated with the first color channel. For example, in accordance with a further advantageous embodiment, in each row and each column of the image sensor (along the course of the respective row or respective column), pixels that are associated with the first color channel alternate with pixels that are not associated with the first color channel. Consequently, the pixels that are associated with the first color channel are arranged in accordance with a pattern that corresponds to the arrangement of black squares on a checkerboard. The pixels of the first color channel that contribute to the autofocus and the remaining pixels that preferably contribute solely to the image recording are thereby homogeneously distributed over the image sensor. In this way, artifacts, in particular direction-dependent artifacts, at transitions between pixels of the one kind and pixels of the other kind may be avoided.

In accordance with an advantageous further development of the above embodiment, the pixels that are not associated with the first color channel are alternately associated in a row-wise manner with a second color channel or a third color channel. (The pixels that are not associated with the first color channel are thereby inevitably also alternately associated in a column-wise manner with the second color channel or the third color channel.) In other words: In every second row (or column) of the image sensor, the pixels that are not associated with the first color channel are associated with the second color channel and in the remaining rows (or columns) of the image sensor, the pixels that are not associated with the first color channel are associated with the third color channel.

While the first color channel is preferably a green color channel, the second color channel is preferably a red color channel and the third color channel is preferably a blue color channel. If the pixels of the image sensor are associated with these three color channels in accordance with the scheme described above, this arrangement corresponds to a so-called Bayer mask. The pixels of an image in RAW format recorded by means of the image sensor are then likewise associated with the three color channels according to the Bayer mask. This advantageously allows the application of established interpolation algorithms for a so-called demosaicing of the RAW image data.

In accordance with one embodiment, each detector element has a detection surface on which the light is incident. In dependence on the light incident on this detection surface, the respective detector element generates said electric charge or said electrical signal. The detection surface may in particular be defined in that only light that is incident on this surface of the detector element contributes to signal or charge generation.

In some embodiments, for each pixel that is associated with the first color channel, the sum of the detection surfaces of the at least two detector elements of the respective pixel may be greater than the detection surface of a detector element of a pixel that is not associated with the first color channel and that comprises only a single detector element. Thus, for pixels that are associated with the first color channel, the effective detection surface is larger than for pixels that comprise only a single detector element. This may in particular be expedient when the first color channel is a green color channel, while the second and third color channel are a red and blue color channel, respectively. This is because pixels of the green color channel usually have a significantly higher light sensitivity than pixels of the blue or red color channel. Due to the larger total detection surface in the case of the pixels of the first (green) color channel, the so-called full-well capacity of the detector elements of a respective pixel of the first (green) color channel is increased and is thus better matched to the full-well capacity of the detector element of a respective pixel of the second (red) or third (blue) color channel.

However, in some embodiments, for each pixel that is associated with the first color channel, the respective detection surface of the at least two detector elements of the respective pixel may be smaller than the detection surface of a detector element of a pixel that is not associated with the first color channel and that comprises only a single detector element.

In some embodiments, each pixel that is associated with the first color channel comprises exactly two detector elements, wherein each pixel that is associated with the first color channel has a total surface that is divided into two halves along a respective division direction, wherein the one detector element of the respective pixel is arranged in the one half and the other detector element of the respective pixel is arranged in the other half. In other words: For the pixels that are associated with the first color channel, the two detector elements of the respective pixel are arranged distributed over two halves of the total surface of the respective pixel that arise by dividing the total surface along a respective division direction.

Said total surface of a pixel may, for example, at least substantially be defined as the intersection of the respective row and the respective column of the image sensor in which the respective pixel is disposed. However, the total surface does not necessarily have to be rectangular, but may be rounded into a circle or have flattened corners and may thus be octagonal, for example.

The respective division direction along which the total surface of a respective pixel is divided into two halves does not have to be the same for all the pixels that are associated with the first color channel. However, all the pixels that are associated with the first color channel are preferably divided along one of exactly two defined division directions that are preferably oriented orthogonally to one another. The total surfaces of at least approximately half of the pixels associated with the first color channel may each be divided into two halves along a first division direction of these two division directions and the total surfaces of the remaining pixels associated with the first color channel may each be divided into two halves along a second division direction of these two division directions.

For all the pixels that are associated with the first color channel, the respective division direction is preferably oriented diagonally to the course of the rows and to the course of the columns of the image sensor. That a respective division direction is oriented diagonally to the course of the rows and to the course of the columns of the image sensor, in particular means that it is neither in parallel with the course of the rows nor in parallel with the course of the columns. The respective division direction may, for example, be oriented at an angle of 45° to the course of the rows and/or to the course of the columns and may in particular correspond to an angle bisector of these two courses.

However, the respective division direction does not necessarily have to be oriented diagonally. For example, the respective division direction may be aligned in parallel with the course of the rows for at least some, in particular for approximately half, of the pixels associated with the first color channel and/or may be aligned in parallel with the course of the columns for at least some, in particular for approximately half, of the pixels associated with the first color channel.

That one of the detector elements of the respective pixel is arranged in one of the halves of the total surface of the respective pixel, in particular means that this detector element is arranged solely within this half. For example, said detection surface of the respective detector element may at least largely fill the respective half. Furthermore, the (detection surfaces of the) two detector elements of a respective pixel associated with the first color channel may at least substantially adjoin one another along the respective division direction, for example, may be separated from one another only by a gap of constant width.

In accordance with an advantageous further development of the above embodiment, each pixel that is associated with the first color channel has a total surface that is alternately divided in a row-wise (or also column-wise) manner along a first division direction or along a second division direction, which is oriented transversely, in particular orthogonally, to the first division direction, into two halves, wherein the one detector element of the respective pixel is arranged in the one half and the other detector element of the respective pixel is arranged in the other half. In other words: In the case of the pixels that are associated with the first color channel, in every second row the two detector elements of the respective pixel are arranged distributed over two halves of the total surface of the respective pixel that arise by dividing the total surface along the first division direction, and in every remaining row the two detector elements of the respective pixel are arranged distributed over two halves of the total surface of the respective pixel that arise by dividing the total surface along the second division direction oriented transversely, in particular orthogonally, to the first division direction. It is preferred if the first division direction is oriented diagonally to the course of the rows and to the course of the columns and/or if the second division direction is oriented diagonally to the course of the rows and to the course of the columns.

If the subject recorded by means of the image sensor has lines or edges that extend in parallel with the division direction along which a respective pixel associated with the first color channel (and thus functioning as a PDAF pixel) is divided, it may be possible that no focus information can be derived from the phase difference between the electrical signals or electric charges of the two detector elements of this pixel. However, if the division line between the two detector elements of a respective pixel associated with the first color channel is alternately oriented in the first division direction or in the second division direction oriented transversely, in particular orthogonally, to said first division direction, this problem may be circumvented since the focus information may be determined, if not based on a pixel divided along the first division direction, then based on a pixel divided along the second division direction. Expediently, the pixels divided along the first division direction and the pixels divided along the second division direction are in this respect, as explained, alternately arranged in a row-wise and column-wise manner and are thus homogeneously distributed on the image sensor. This is because, due to this arrangement, the nearest neighbors of a pixel divided along the first division direction are divided along the second division direction and, vice versa, the nearest neighbors of a pixel divided along the second division direction are divided along the first division direction so that the information required for the autofocus may be reliably determined in each region of the image sensor based on the pixels associated with the first color channel.

In accordance with a further advantageous embodiment, intermediate spaces are provided between the pixels and are adjoined by four pixels in each case, wherein the image sensor comprises readout electronics that extend into the intermediate spaces. Thus, said intermediate space is surrounded by four pixels that adjoin the intermediate space. For each of the intermediate spaces, it is preferably: two pixels that are associated with the first color channel, one pixel that is associated with the second color channel, and one pixel that is associated with the third color channel. The four pixels are arranged as a quadrangle, in particular as a square, so that two of the four pixels are therefore located in the same row and the other two pixels are located in the same row adjacent thereto (or that two of the four pixels are located in the same column and the other two pixels are located in the same column adjacent thereto).

In this embodiment, each detector element further has a transfer gate at which an electric charge generated by the detector element may be output to the readout electronics, wherein each intermediate space is adjoined by at least one transfer gate of a detector element of a pixel adjoining the intermediate space and by at most one further transfer gate of a detector element of a further pixel adjoining the intermediate space. This means that no further transfer gate may adjoin the respective intermediate space. In other words: Each intermediate space is adjoined by either exactly one transfer gate or exactly two transfer gates, wherein the two transfer gates are transfer gates of different pixels adjoining the intermediate space. Each transfer gate may in particular be arranged in one of four corner regions of the respective pixel (i.e. of the pixel by which the detector element with the transfer gate is encompassed) that are oriented diagonally to the course of the rows and columns. Common alternative designations for transfer gate are transmission gate and transmission grid.

In particular, it is preferred if, both along the course of the rows and along the course of the columns of the image sensor, intermediate spaces that are adjoined by exactly one transfer gate just alternate with intermediate spaces that are adjoined by two transfer gates.

In accordance with a further development of the above embodiments, for each pixel that is associated with the first color channel and whose total surface is divided along the first division direction, the transfer gates of its two detector elements are arranged opposite one another with respect to the second division direction and, vice versa, for each pixel that is associated with the first color channel and whose total surface is divided along the second division direction, the transfer gates of its two detector elements are arranged opposite one another with respect to the first division direction. For this purpose, the transfer gates may in particular be arranged in those two of the four corner regions of the respective pixel which are opposite one another with respect to the respective division direction. Furthermore, it is preferred if for each pixel that is not associated with the first color channel, the transfer gate of its detector element is arranged facing in the first division direction. For this purpose, the transfer gate may in particular be arranged in that one of the four corner regions of the respective pixel that faces in the first division direction. In this way, a balanced arrangement of the transfer gates is achieved in which the readout electronics in each case only have to read out either one or two transfer gates in the intermediate spaces between the pixels.

In accordance with another further development of the above embodiments, the readout electronics comprise a plurality of source follower transistors and each transfer gate is electrically connected to one of the source follower transistors so that the electric charge generated by the respective detector element (i.e. by that detector element which has the transfer gate) may be read out via the source follower transistor, wherein, for two transfer gates that adjoin the same intermediate space, both transfer gates are in each case electrically connected to the same source follower transistor so that the electric charge generated by the respective detector elements (i.e. by those detector elements which have a respective one of the two transfer gates) may be read out via a single common source follower transistor (namely said source follower transistor to which both source follower transistors are electrically connected). In those intermediate spaces which are adjoined by two transfer gates, a so-called 2× shared pixel architecture is therefore provided in which the charge of two pixels is read out via a common source follower transistor. Such an architecture is in particular advantageous for space reasons.

A field-effect transistor that is connected in a source follower circuit (also called a common drain circuit) is designated as a source follower transistor. The source follower transistor may also refer to the entire source follower circuit (common drain circuit). The transfer gates are electrically connected to the input of the respective source follower circuit (common drain circuit).

In the following, the invention will be explained further only by way of example with reference to the FIGURE.

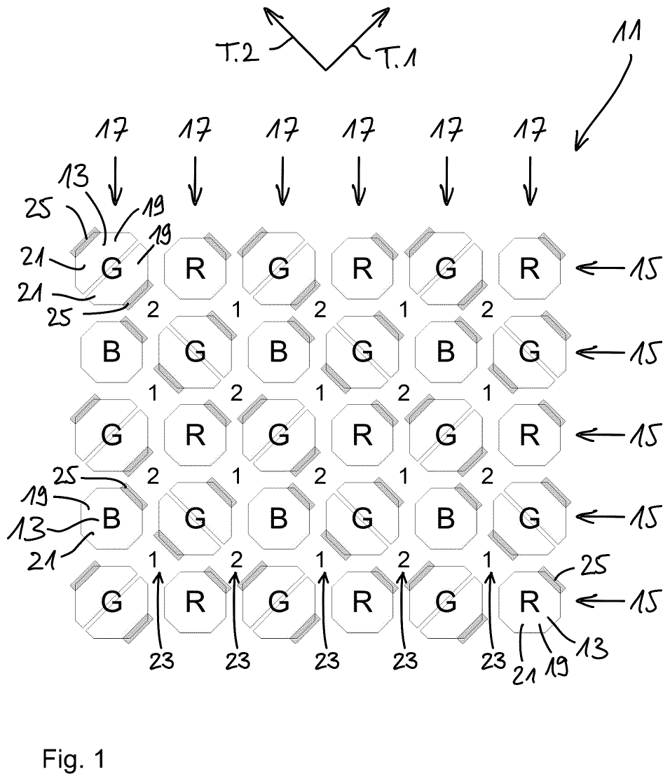

FIG. 1 shows a detail of an image sensor configured in accordance with a possible embodiment of the invention in a schematic representation.

The image sensor 11 shown in FIG. 1 is configured as a CMOS image sensor and may in particular be used as an image sensor for an electronic camera (not shown). The image sensor 11 comprises a plurality of pixels 13 that are arranged as a pixel matrix in rows 15 and columns 17. The rows 15, which extend horizontally in FIG. 1, and the columns 17, which extend vertically in FIG. 1, each have a rectilinear course and are oriented orthogonally to one another with respect to their respective courses.

The image sensor 11 may, for example, have a 4K resolution or an even higher resolution. Thus, the image sensor 11 may, for example, have 4096 columns 17 and, depending on the format, a corresponding number of rows 15, for example 3072 or 2304 rows 15. The respective height of the rows 15 and the respective width of the columns 17 are preferably identical. In FIG. 1, only a detail of the image sensor 11 is shown that comprises five rows 15 and six columns 17. The pattern according to which the pixels 13 are arranged on the entire image sensor 11 may be reproduced based on this detail.

The image sensor 11 has three color channels, namely a first color channel G, which is a green color channel, a second color channel R, which is a red color channel, and a third color channel B, which is a blue color channel. Each pixel 13 of the image sensor 11 is associated with one of these three color channels G, R, B. The pixels 13 associated with the first color channel G are indicated by a “G” in FIG. 1, the pixels 13 associated with the second color channel R are indicated by an “R” in FIG. 1, and the pixels 13 associated with the third color channel B are indicated by a “B” in FIG. 1.

As can be seen in FIG. 1, in each row 15 and each column 17 of the image sensor 11, pixels 13 that are associated with the first color channel G alternate with pixels 13 associated with the second color channel R or the third color channel B. The pixels 13 associated with the first color channel G are thereby arranged in the manner of a checkerboard. Consequently, every second pixel 13 of the image sensor 11 is associated with the first color channel G.

The pixels 13 that are not associated with the first color channel G are alternately associated in a row-wise manner with the second color channel R or the third color channel B. Due to the checkerboard-like arrangement of the pixels 13 associated with the first color channel G, this also applies column-wise. Thus, the pixels 13 associated with the second color channel R are located in the first, third and fifth rows 15 and in the second, fourth and sixth columns 17 in the detail shown in FIG. 1; the pixels 13 associated with the third color channel B are located in the second and fourth rows 15 and in the first, third and fifth columns 17 in the detail shown in FIG. 1.

The described spatial arrangement of the pixels 13 associated with the first color channel G, the second color channel R and the third color channel B corresponds to a so-called Bayer mask that is generally used for image sensors 11. This makes the image sensor 11 compatible with common RAW workflows.

Each pixel 13 comprises at least one light-sensitive detector element 19 that is configured to generate electrical signals in the form of electric charge in dependence on light incident on a detection surface 21 of the respective detector element 19. All the detector elements 19 of the pixels 13 are arranged with their detection surfaces 21 in a common plane of the image sensor 11.

If a respective pixel 13 comprises a single detector element 19, its detection surface 21 is at least approximately round, namely octagonal in the embodiment shown. In the case of pixels 13 that comprise two detector elements 19, the two detection surfaces 21 of these detector elements 19 are together at least approximately round, namely octagonal in the embodiment shown, with a narrow rectilinear gap of constant width extending between the two detection surfaces 21. In particular due to the approximately round shape of the pixels 13, the image sensor 11 has intermediate spaces 23 between the pixels 13. Each intermediate space 23 is surrounded by four pixels 13 such that these four pixels 13 (with a respective corner region) adjoin the respective intermediate space 23.

Each detector element 19 furthermore has a transfer gate 25 which is arranged facing in a diagonal direction with respect to the course of the rows 15 and columns 17 (namely in one of the respective four corner regions of the respective pixel 13) and at which an electric charge generated by the detector element 19 may be output to readout electronics of the image sensor 11. For this purpose, the readout electronics (not shown) extend into said intermediate spaces 23.

Of each pixel 13, in each case only the one or the two detector elements 19 are shown in FIG. 1. Of each detector element 19, its detection surface 21 is shown outlined and colored in light gray in each case, while the respective transfer gate 25 is shown as a strip colored in dark gray.

Furthermore, each pixel 13 comprises a color filter that only transmits light of the color corresponding to the respective color channel G, R or B with which the respective pixel 13 is associated to the detector element 19 or the two detector elements 19 of the respective pixel 13. In this way, only that portion of the light is incident on the detector element 19 or the detector elements 19 of a respective pixel 13 which has the color corresponding to the respective color channel G, R or B so that the signal generated by the detector element 19 or the detector elements 19 is also only dependent on the intensity of this portion of the light. Each pixel 13 further comprises a microlens that extends across the detector element 19 or the two detector elements 19 of the respective pixel 13 and collects the incident light. The color filter and the microlens of a respective pixel 13 are not shown in FIG. 1.

In accordance with the invention, all the pixels 13 of the image sensor 11 that are associated with the first color channel G each comprise two detector elements 19. In contrast, the pixels 13 of the image sensor 11 that are associated with the second color channel R or the third color channel B each comprise only a single detector element 19. The pixels 13 associated with the first color channel G may thereby be used as PDAF pixels by forming a phase difference between the electrical signals generated by the two detector elements 19 of the respective pixel 13, which phase difference may be used to determine a focus setting in accordance with which a focus drive of the camera is to be controlled for an automatic focusing of the lens. An evaluation circuit (not shown), which is configured to determine a phase difference from the signals of the two detector elements 19 of the respective pixel 13, may be associated with the image sensor 11 for this purpose. The evaluation circuit may further be configured to determine information about a focus distance of the image sensor 11 or of the camera from the phase difference. The evaluation circuit may be integrated into the image sensor 11 or formed separately therefrom, in particular as an analog or digital circuit. The evaluation circuit may be connected to said readout electronics.

For each pixel 13 that is associated with the first color channel G, the two detector elements 19 of the respective pixel 13 are arranged distributed over two halves of the total surface of the respective pixel 13 that arise by dividing the total surface either along a first division direction T.1 (cf. arrow) oriented diagonally to the course of the rows 15 and to the course of the columns 17 or along a second division direction T.2 (cf. arrow) oriented diagonally to the course of the rows 15 and to the course of the columns 17. Both division directions T.1 and T.2 each have an angle of 45° with respect to both the course of the rows 15 and the course of the columns 17 of the image sensor 11, wherein the first division direction T. 1 is oriented orthogonally to the second division direction T.2.

In which of the two division directions T.1 and T.2 a respective pixel 13 associated with the first color channel G is divided depends on the row 15 or column 17 in which this pixel 13 is located. In every second row 15 (in FIG. 1 in the first, the third and the fifth row 15) or in every second column 17 (in FIG. 1 in the first, the third and the fifth column 17), the pixels 13 associated with the first color channel G are divided along the first division direction T.1, while in the other rows 15 (in FIG. 1 in the second and the fourth row 15) or in the other columns 17 (in FIG. 1 in the second, the fourth and the sixth column 17), said pixels 13 are divided along the second division direction T.2. The row-wise and column-wise alternating division of the pixels 13 of the first color channel G, which are usable as PDAF pixels, into the two mutually orthogonal division directions T.1 and T.2 prevents the autofocus based on the phase difference between the signals of two detector elements 19 of a respective pixel 13 from possibly not functioning in regions of the subject that have a line pattern or edges.

While for each pixel 13 that is associated with the second color channel R or the third color channel B, the transfer gate 25 of the detector element 19 is arranged facing in the first division direction T.1, for the pixels 13 that are associated with the first color channel G, the arrangement of the transfer gates 25 of the two detector elements 19 of the respective pixel 13 depends on along which of the two division directions T.1 and T.2 the respective pixel 13 is divided. If the pixel 13 is divided along the first division direction T.1, the transfer gates 25 of its two detector elements 19 are arranged opposite one another with respect to the second division direction T.2 (i.e. facing in the second division direction T.2 or opposite the second division direction T.2); if, on the other hand, the pixel 13 is divided along the second division direction T.2, the transfer gates 25 of its two detector elements 19 are arranged opposite one another with respect to the first division direction T.1 (i.e. facing in the first division direction T.1 or opposite the first division direction T.1).

As can be seen in FIG. 1, this arrangement of the transfer gates 25 has the result that two transfer gates 25 adjoin every second intermediate space 23 row-wise and column-wise, while in each case only one transfer gate 25 adjoins the remaining intermediate spaces 23. The intermediate spaces 23 adjoined by one transfer gate 25 are indicated by the numeral “1” in FIG. 1, while the intermediate spaces 23 adjoined by two transfer gates 25 are indicated by the numeral “2” in

FIG. 1.

Each transfer gate 25 is electrically connected to a source follower transistor (not shown) of the readout electronics so that the respective detector element 19 may be read out via it. A separate source follower transistor is provided for each transfer gate 25 that is the only transfer gate 25 adjoining a respective intermediate space 23. In contrast, two transfer gates 25 that adjoin the same intermediate space 23 are electrically connected to a single (i.e. both to the same) source follower transistor so that the electric charges of the two corresponding detector elements 19 are read out via a common source follower transistor in accordance with a 2× shared pixel architecture. The readout electronics may thereby be designed in a particularly space-saving manner.

Since, in the image sensor 11, all the pixels 13 of the first color channel G may be used as PDAF pixels due to their design with two detector elements 19, all the 2×2 cells in the pixel matrix (each consisting of two green pixels arranged diagonally opposite one another and a red pixel and a blue pixel) are identical to one another. Unlike in the case of an image sensor that has only individual PDAF pixels arranged in a scattered manner, no interpolation is therefore required. Furthermore, the two electrical signals that are generated by the two detector elements 19 of a respective pixel 13 associated with the first color channel G may be summed to obtain the “normal” image information (intensity of the green portion of the light at this location) for the position of the respective pixel 13. Also for this reason, the pixels 13 of the first color channel G functioning as PDAF pixels did not need to be interpolated.

Since only the pixels 13 associated with the first color channel G comprise two detector elements 19 and are thus suitable as PDAF pixels, whereas the pixels 13 associated with the second color channel R and the third color channel B are not, the data rate (bandwidth of the signals generated by the pixels 13) in the image sensor 11 increases by only 50% compared to an increase by at least 100% for image sensors in which all the pixels are configured as PDAF pixels in that they comprise at least two detector elements 19. Therefore, in the image sensor 11 in accordance with the invention, the power dissipation may also be kept comparatively low.

It is not only essential that fewer pixels 13 comprise two detector elements 19 than in the case of an image sensor equipped with PDAF pixels over the full area, but also that it depends on the respective color channel G, R or B whether a respective pixel 13 comprises two detector elements 19 or one detector element 19. It is particularly advantageous if the pixels 13 that comprise two detector elements 19 are pixels 13 that are associated with the green color channel G since the green color channel G corresponds to luminance and thus carries the bulk of the image information. Furthermore, in the case of an image sensor 11 with a Bayer mask, the density of the pixels 13 associated with the green color channel G is higher than the density of the pixels 13 associated with the red color channel R and the blue color channel B, respectively. This has the result that the image sensor 11 in accordance with the invention delivers similarly good results for the autofocus to an image sensor equipped with PDAF pixels over the full area at a significantly reduced data rate.

### REFERENCE NUMERALS

11 image sensor
13 pixel
15 row
17 column
19 detector element
21 detection surface
23 intermediate space
25 transfer gate

1. An image sensor for an electronic camera, said image sensor comprising a plurality of pixels which are arranged in rows and columns and each of which is associated with one of at least three color channels,
wherein each pixel comprises at least one light-sensitive detector element, which generates electrical signals in dependence on incident light, and a color filter that filters the light prior to incidence on the at least one detector element in accordance with the color channel with which the respective pixel is associated,
characterized in that
each pixel that is associated with a first color channel of the three color channels comprises at least two light-sensitive detector elements that generate electrical signals independently of one another in dependence on incident light so that a phase difference between the electrical signals generated by the detector elements of the respective pixel can be used for an autofocus of the camera, whereas, of the pixels that are not associated with the first color channel, at least some comprise only a single light-sensitive detector element that generates electrical signals in dependence on incident light.

2. The image sensor according to claim 1,
wherein most of the pixels that are not associated with the first color channel comprise only a single light-sensitive detector element that generates electrical signals in dependence on incident light.

3. The image sensor according to claim 1,
wherein all of the pixels that are not associated with the first color channel comprise only a single light-sensitive detector element that generates electrical signals in dependence on incident light.

4. The image sensor according to claim 1,
wherein at least half of the pixels of the image sensor are associated with the first color channel.

5. The image sensor according to claim 1,
wherein, in each row and each column of the image sensor, pixels that are associated with the first color channel alternate with pixels that are not associated with the first color channel.

6. The image sensor according to claim 5,
wherein the first color channel is a green color channel.

7. The image sensor according to claim 5,
wherein the pixels that are not associated with the first color channel are alternately associated in a row-wise manner with a second color channel or a third color channel.

8. The image sensor according to claim 7,
wherein the second color channel is a red color channel.

9. The image sensor according to claim 7,
wherein the third color channel is a blue color channel.

10. The image sensor according to claim 1,
wherein each detector element has a detection surface on which the light is incident, and
wherein, for each pixel that is associated with the first color channel, the sum of the detection surfaces of the at least two detector elements of the respective pixel is greater than the detection surface of the detector element of a pixel that is not associated with the first color channel and that comprises only a single detector element.

11. The image sensor according to claim 10,
wherein the pixels of the image sensor are arranged at positions that form a regular grid of rows and columns, wherein the at least two light-sensitive detector elements of the pixels that are associated with the first color channel are jointly arranged at a single position of the grid.

12. The image sensor according to claim 1,
wherein each pixel that is associated with the first color channel comprises exactly two detector elements, and
wherein each pixel that is associated with the first color channel has a total surface that is divided into two halves along a respective division direction that is oriented diagonally to the course of the rows and to the course of the columns, wherein the one detector element of the respective pixel is arranged in the one half and the other detector element of the respective pixel is arranged in the other half.

13. The image sensor according to claim 12,
wherein each pixel that is associated with the first color channel has a total surface that is alternately divided in a row-wise manner along a first division direction, which is oriented diagonally to the course of the rows and to the course of the columns, or along a second division direction, which is oriented diagonally to the course of the rows and to the course of the columns and which is oriented transversely to the first division direction, into two halves, wherein the one detector element of the respective pixel is arranged in the one half and the other detector element of the respective pixel is arranged in the other half.

14. The image sensor according to claim 13,
wherein the second division direction is oriented orthogonally to the first division direction.

15. The image sensor according to claim 1,
wherein intermediate spaces are provided between the pixels and are adjoined by four pixels in each case,
wherein the image sensor comprises readout electronics that extend into the intermediate spaces,
wherein each detector element has a transfer gate at which an electric charge generated by the detector element can be output to the readout electronics, and
wherein each intermediate space is adjoined by at least one transfer gate of a detector element of a pixel adjoining the intermediate space and by at most one further transfer gate of a detector element of a further pixel adjoining the intermediate space.

16. The image sensor according to claim 13,
wherein intermediate spaces are provided between the pixels and are adjoined by four pixels in each case,
wherein the image sensor comprises readout electronics that extend into the intermediate spaces,
wherein each detector element has a transfer gate at which an electric charge generated by the detector element can be output to the readout electronics,
wherein each intermediate space is adjoined by at least one transfer gate of a detector element of a pixel adjoining the intermediate space and by at most one further transfer gate of a detector element of a further pixel adjoining the intermediate space,
wherein, for each pixel that is associated with the first color channel and whose total surface is divided along the first division direction, the transfer gates of its two detector elements are arranged opposite one another with respect to the second division direction,
wherein, for each pixel that is associated with the first color channel and whose total surface is divided along the second division direction, the transfer gates of its two detector elements are opposite one another with respect to the first division direction, and
wherein, for each pixel that is not associated with the first color channel, the transfer gate of its detector element is arranged facing in the first division direction.

17. The image sensor according to claim 15,
wherein the readout electronics comprise a plurality of source follower transistors and each transfer gate is electrically connected to one of the source follower transistors so that the electric charge generated by the respective detector element can be read out via the source follower transistor, and
wherein, for two transfer gates that adjoin the same intermediate space, both transfer gates are in each case electrically connected to the same source follower transistor so that the electric charge generated by the respective detector elements can be read out via a single common source follower transistor.

18. The image sensor according to claim 1,
wherein the image sensor is a CMOS image sensor.

19. An image sensor for an electronic camera, said image sensor comprising a plurality of pixels which are arranged in rows and columns and each of which is associated with one of at least three color channels,
wherein each pixel comprises at least one light-sensitive detector element, which generates electrical signals in dependence on incident light, and a color filter that filters the light prior to incidence on the at least one detector element in accordance with the color channel with which the respective pixel is associated,
wherein each pixel that is associated with a first color channel of the three color channels comprises at least two light-sensitive detector elements that generate electrical signals independently of one another in dependence on incident light so that a phase difference between the electrical signals generated by the detector elements of the respective pixel can be used for an autofocus of the camera, whereas, of the pixels that are not associated with the first color channel, at least some comprise only a single light-sensitive detector element that generates electrical signals in dependence on incident light,
wherein the pixels of the image sensor are arranged at positions that form a regular grid of rows and columns, wherein the at least two light-sensitive detector elements of the pixels that are associated with the first color channel are jointly arranged at a single position of the grid,
wherein each detector element has a detection surface on which the light is incident, and
wherein, for each pixel that is associated with the first color channel, the sum of the detection surfaces of the at least two detector elements of the respective pixel is greater than the detection surface of the detector element of a pixel that is not associated with the first color channel and that comprises only a single detector element.

20. An image sensor for an electronic camera, said image sensor comprising a plurality of pixels which are arranged in rows and columns and each of which is associated with one of at least three color channels,
wherein each pixel comprises at least one light-sensitive detector element, which generates electrical signals in dependence on incident light, and a color filter that filters the light prior to incidence on the at least one detector element in accordance with the color channel with which the respective pixel is associated,
wherein each pixel that is associated with a first color channel of the three color channels comprises at least two light-sensitive detector elements that generate electrical signals independently of one another in dependence on incident light so that a phase difference between the electrical signals generated by the detector elements of the respective pixel can be used for an autofocus of the camera, whereas, of the pixels that are not associated with the first color channel, at least some comprise only a single light-sensitive detector element that generates electrical signals in dependence on incident light,
wherein each pixel that is associated with the first color channel comprises exactly two detector elements,
wherein each pixel that is associated with the first color channel has a total surface that is divided into two halves along a respective division direction that is oriented diagonally to the course of the rows and to the course of the columns, wherein the one detector element of the respective pixel is arranged in the one half and the other detector element of the respective pixel is arranged in the other half,
wherein each pixel that is associated with the first color channel has a total surface that is alternately divided in a row-wise manner along a first division direction, which is oriented diagonally to the course of the rows and to the course of the columns, or along a second division direction, which is oriented diagonally to the course of the rows and to the course of the columns and which is oriented transversely to the first division direction, into two halves, wherein the one detector element of the respective pixel is arranged in the one half and the other detector element of the respective pixel is arranged in the other half.
